(19) United States
(12) Patent Application Publication
(10) Pub. No.: US 2021/0249545 A1
(43) Pub. Date: Aug. 12, 2021

(54) OPTOELECTRONIC DEVICES HAVING A DILUTE NITRIDE LAYER

(71) Applicant: Array Photonics, Inc., Tempe, AZ (US)

(72) Inventors: Radek ROUCKA, East Palo Alto, CA (US); Sabeur SIALA, Sunnyvale, CA (US); Aymeric MAROS, San Francisco, CA (US)

(21) Appl. No.: 17/251,110

(22) PCT Filed: Jun. 12, 2019
(86) PCT No.: PCT/US2019/036857

§ 371 Date: Dec. 10, 2020

Related U.S. Application Data
(60) Provisional application No. 62/685,039, filed on Jun. 14, 2018.

(51) Int. Cl. H01L 31/0304; H01L 31/107; H01L 31/0352; H01L 31/18

(52) U.S. Cl. CPC H01L 31/03048; H01L 31/1075; H01L 31/1856; H01L 31/1848; H01L 31/035236

(57) ABSTRACT

Optoelectronic devices having GaInNAsSb, GaInNAsBi or GaInNAsSbBi active layers are disclosed. The optoelectronic devices have an active or absorbing layer, with a bandgap within a range from 0.7 eV and 1.2 eV. The active layer is coupled to a multiplication layer. The multiplication layer is designed to provide a large optical gain with a high signal-to-noise ratio at low light levels at wavelengths up to 1.8 μm.

This application claims the benefit under 35 U.S.C. § 119(e) of U.S. Provisional Application No. 62/685,039, filed on Jun. 14, 2018, which is incorporated by reference in its entirety.

### FIELD

The disclosure relates to shortwave infrared (SWIR) optoelectronic devices operating within the wavelength range of 0.9 μm to 1.8 μm including photodetectors, photodetector arrays, and avalanche photodetectors.

### BACKGROUND

Optoelectronic devices operating in the infrared wavelength range between 0.9 μm and 1.8 μm range have a wide range of applications, including fiber optic communications, sensing, and imaging Traditionally, compound III-V semiconductor materials are used to make such devices. Indium gallium arsenide (InGaAs) materials are usually grown on indium phosphide (InP) substrates. The composition and thickness of the InGaAs layers are chosen to provide the required functionality, such as light emission or absorption at desired wavelengths of light and are also lattice-matched or very closely lattice-matched to the InP substrate to produce high quality materials that have low levels of crystalline defects, and high levels of performance.

With respect to photodetectors, devices that can be produced include high-speed photodetectors for telecommunications applications, and arrays of photodetectors that can be used as sensors and imagers for military, biomedical, industrial, environmental, and scientific applications. In such applications, photodetectors with high responsivity, low dark current, and low noise are desirable.

Although InGaAs on InP materials currently dominate the SWIR photodetector market, the material system has several limitations, including the high cost of InP substrates, low yields due to fragility of the InP substrates, and limited InP wafer diameter (and associated quality issues at larger diameters). From a manufacturing perspective, and also from an economic perspective, gallium arsenide (GaAs) represents a better substrate choice. However, the large lattice mismatch between GaAs and the InGaAs alloys required for infrared devices produces poor quality materials that compromise electrical and optical performance. Attempts have been made at producing long-wavelength (greater than 1.2 μm) materials for photodetectors on GaAs, based on dilute nitride materials such as GaInNAs and GaInNAsSb. However, where device performance is reported, it has been much poorer than for InGaAs/InP devices, for example, very low responsivity, which renders the materials unsuited for practical sensing and detection applications. Other considerations for photodetectors include dark current, and specific responsivity.

For example, Cheah et al., “GaAs-Based Heterojunction p-i-n Photodetectors Using Pentenary InGaAsNSb as the Intrinsic Layer”, IEEE Photon. Technol. Letts., 17(9), pp. 1932-1934 (2005), and Loke et al., “Improvement of GaInNAs p-i-n photodetector responsivity by antimony incorporation”, J. Appl. Phys. 101, 033122 (2007), report photodetectors having a responsivity of only 0.097 A/W at a wavelength of 1300 nm.

Tan et al., “GaInNAsSb/GaAs Photodiodes for Long Wavelength Applications, IEEE Electron. Dev. Letts., 32(7), pp. 919-921 (2011) describe photodiodes having a responsivity of only 0.18 A/W at a wavelength of 1300 nm.

In U.S. Application Publication No. 2016/0372624, Yanka et al. disclose optoelectronic detectors having dilute nitride layers (InGaNAsSb). Although certain parameters that relate to semiconductor material quality are described, no working detectors having practical efficiencies are taught within the broad compositional range disclosed.

Co-pending U.S. Application Publication No. 2019/0013430 A1, which is incorporated herein by reference in its entirety, describes dilute nitride detectors having responsivities greater than 0.6 A/W at a wavelength of 1300 nm.

In sensing and imaging applications such as environmental monitoring and night vision, the optical signal levels can be low, and so internal gain provided by an avalanche photodiode (APD) is desirable. Tan et al. in suggested that GaInNAsSb materials could be used as an absorber layer in GaAs-based APDs, employing an Al_{0.8}Ga_{0.2}As avalanche layer. In addition to the multiplication factor of the APD, the noise performance of the detector is also important. Multiplication can result in excess noise related to the stochastic or statistical nature of the avalanche (or impact ionization) process. The excess noise factor is a function of the carrier ionization ratio, k, where k is usually defined as the ratio of hole to electron ionization probabilities (k≤1). Tan et al., in “Experimental evaluation of impact ionization in dilute nitride GaInNAs diodes”, Appl. Phys. Lett. 102, 102101 (2013), describe the impact ionization process in dilute nitride GaInNAs diodes. For alloys with low nitrogen composition <2%, the asymmetry in ionization coefficients is not sufficient, and is similar to values reported for GaAs. However, while k could be enhanced by a factor of 4 for compositions with a nitrogen content greater than about 2%, suppressed impact ionization coefficients limit the ability of those materials to provide adequate multiplication behavior in an avalanche photodetector.

Thus, to take advantage of the manufacturing scalability and cost advantages of GaAs substrates, there is continued interest in developing long-wavelength materials on GaAs that have improved optoelectronic performance, with improved multiplication characteristics and low noise characteristics.

### SUMMARY

According to the present invention, semiconductor optoelectronic devices comprise: a substrate; a first barrier layer overlying the substrate; a multiplication layer overlying the first barrier layer; wherein the multiplication layer comprises Ga₁₋ₓInₓN_{y}As_{1-y-z}(Sb,Bi)_{z}, wherein 0≤x≤0.4, 0≤y≤0.07, and 0≤z≤0.2. an active layer overlying the multiplication layer, wherein, the active layer comprises a lattice matched or pseudomorphic dilute nitride material; and the dilute nitride material has a bandgap within a range from 0.7 eV and 1.2 eV; and a second barrier layer overlying the active layer.

According to the present invention, methods of forming a semiconductor optoelectronic devices comprise forming a first barrier layer overlying a substrate; forming a multiplication layer overlying the first barrier layer, wherein the multiplication layer comprises Ga₁₋ₓInₓN_{y}As_{1-y-z}(Sb,Bi)_{z}, wherein 0≤x≤0.4, 0≤y≤0.07, and 0<z≤0.2; forming an active layer overlying the multiplication layer, wherein, the active layer comprises a pseudomorphic dilute nitride material; and the dilute nitride material has a bandgap within a range from 0.7 eV and 1.2 eV; and forming a second barrier layer overlying the active layer.

### BRIEF DESCRIPTION OF THE DRAWINGS

The drawings described herein are for illustration purposes only. The drawings are not intended to limit the scope of the present disclosure.

FIG. 1 shows a side view of a semiconductor optoelectronic device according to the present invention.

FIG. 2 shows a side view of another semiconductor optoelectronic device according to the present invention.

FIG. 3 shows a side view of another semiconductor optoelectronic device according to the present invention.

FIG. 4 shows a side view of an avalanche photodetector according to the present invention.

FIG. 5 shows a schematic band edge diagram for an avalanche photodiode with separate absorber, charge and multiplication layers according to the present invention.

FIGS. 6A and 6B show schematic band edge diagrams of a multiplication region having two linearly graded interlayers at zero bias and under reverse bias, respectively.

FIGS. 6C and 6D show schematic band edge diagrams of a multiplication region having a single non-linearly graded layer at zero bias.

FIG. 7 shows a schematic band edge diagram for a four-period superlattice multiplication region.

FIG. 8 shows a schematic band edge diagram for a two-period superlattice multiplication region with step-graded interlayers.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized, and structural, logical, and electrical changes may be made without departing from the scope of the invention. The various embodiments disclosed herein are not necessarily mutually exclusive, as some disclosed embodiments may be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

The term “lattice matched” as used herein means that the two referenced materials have the same lattice constant or a lattice constant differing by up to +/−0.2%. For example, GaAs and AlAs are lattice matched, having lattice constants differing by 0.12%, and are considered to be lattice matched.

The term “pseudomorphically strained” as used herein means that layers made of different materials with a lattice constant difference up to +/−2% can be grown on top of a lattice matched or strained layer without generating misfit dislocations. The lattice parameters can differ, for example, by up to +/−1%, by up to +/−0.5%, or by up to +/−0.2%.

The term “layer” as used herein, means a continuous region of a material (e.g., an alloy) that can be uniformly or non-uniformly doped and that can have a uniform or a non-uniform composition across the region.

The term “bandgap” as used herein is the energy difference between the conduction and valence bands of a material.

The term “responsivity” as used herein is the ratio of the generated photocurrent to the incident light power at a given wavelength.

FIG. 1 shows a side view of an example of a semiconductor optoelectronic device 100 according to the present invention. Semiconductor optoelectronic device 100 comprises a p-i-n diode and a multiplication layer. Device 100 comprises a substrate 102, a first doped layer 104, a multiplication layer 106, an active (or absorber) layer 108, and a second doped layer 110. For simplicity, each layer is shown as a single layer. However, it will be understood that each layer can include one or more layers with differing compositions, thicknesses, and doping levels to provide an appropriate optical and/or electrical functionality, and to improve interface quality, electron transport, hole transport and/or other optoelectronic properties. The purpose of the multiplication layer 106 is to amplify the photocurrent generated by the active region of a photodetector device. The structure of device 100 provides an avalanche photodiode (APD). An APD introduces an additional p-n junction into the structure, as well as introduces an additional thickness. This allows a higher reverse bias voltage to be applied to the device, which results in carrier multiplication by the avalanche process.

An APD is an example of an optoelectronic device provided by the present disclosure. Examples of other optoelectronic devices include photovoltaic cells, lasers, photodiodes, phototransistors, photomultipliers, single-photon avalanche photodetectors, optoisolators, integrated optical circuits, photoresistors, charge-coupled imaging devices, quantum cascade lasers, multiple quantum well devices, and optocouplers. Although APDs are referred to throughout the specification, it will be understood that the structures, materials, and properties can be used in other optoelectronic devices.

Substrate 102 can have a lattice constant that matches or nearly matches the lattice constant of GaAs or Ge. The substrate can be, for example, GaAs, Ge or a buffered silicon substrate that has a lattice constant approximately equal to that of GaAs or Ge. Substrate 102 may be doped p-type, or n-type, or may be a semi-insulating (SI substrate). The thickness of substrate 102 can be chosen to be any suitable thickness. Substrate 102 can include one or more layers, for example, a Si layer having an overlying SiGeSn buffer layer that is engineered to have a lattice constant that matches or nearly matches the lattice constant of GaAs or Ge. This can mean the substrate has a lattice parameter different than that of GaAs or Ge by less than or equal to 3%, less than 1%, or less than 0.5% of the lattice constant of GaAs or Ge.

First doped layer 104 can have a doping of one type and the second doped layer 210 can have a doping of the opposite type. If first doped layer 104 is doped n-type, second doped layer 110 is doped p-type. Conversely, if first doped layer 104 is doped p-type, second doped layer 110 is doped n-type. Examples of p-type dopants include C and Be. Examples of n-type dopants include Si and Te. Doped layers 104 and 110 can be chosen to have a composition that is lattice matched or pseudomorphically strained to the substrate. The doped layers can comprise any suitable III-V material, such as GaAs, AlGaAs, GaInAs, GaInP, GaInPAs, GaInNAs, GaInNAsSb. The bandgap of the doped layers can be selected to be larger than the bandgap of active layer 108. Doping levels can be within a range from 1×10¹⁵ cm⁻³ to 2×10¹⁹ cm⁻³. Doping levels may be constant within a layer and/or the doping profile may be graded, for example, increasing the doping level from a minimum value to a maximum value as a function of the distance from the interface between the doped layer and the active layer. Doped layers 104 and 110 can have a thickness, for example, within a range from 50 nm and 3 μm.

Active layer 108 can be lattice matched or pseudomorphically strained with respect to the substrate and/or to the doped layers. The bandgap of active layer 108 can be lower than that of the doped layers 104 and 110. Active layer 108 can comprise a layer capable of processing light over a desired wavelength range. Processing is defined to be a light emission, a light receiving, a light sensing and light modulation.

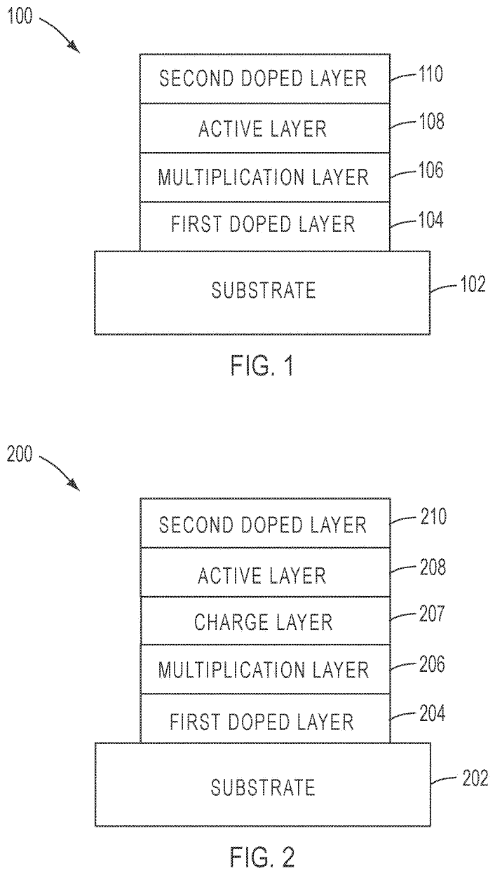

Active layer 108 can include a dilute nitride material. The dilute nitride material can be Ga₁₋ₓInₓN_{y}As_{1-y-z}Sb_{z}, where x, y and z can be 0≤x≤0.4, 0≤y≤0.07 and 0<z≤0.2, respectively. In some embodiments, x, y and z can be 0.01≤x≤0.4, 0.02≤y≤0.07 and 0.001≤z≤0.04, respectively. Active layer 108 can have a bandgap within a range from 0.7 eV to 1.2 eV such that the active layer can absorb or emit light at wavelengths up to 1.8 μm. Bismuth (Bi) may be added as a surfactant during growth of the dilute nitride, improving material quality (such as defect density), and the device performance. The thickness of active layer 108 can be within a range, for example, from 0.2 μm to 10 μm, such as from 1 μm to 4 μm. Active layer 108 can be compressively strained with respect to the substrate 102. Strain can also improve device performance. For a photodetector, the device performance of most relevance includes the dark current, operating speed, noise and responsivity. Active layer 108 can comprise an intrinsic layer or an unintentionally doped layer. Unintentionally doped semiconductors do not have dopants intentionally added but can include a nonzero concentration of impurities that act as dopants. The carrier concentration of the active layer can be, for example, less than 1×10¹⁶ cm⁻³ (measured at room temperature), less than 5×10¹⁵ cm⁻³, or less than 1×10¹⁵ cm⁻³. However, active layer 108 can be doped close to the interface with overlying doped layer 110 and/or the underlying multiplication layer 106 (or charge layer 207 in FIG. 2). The composition of active layer 108 can also be increased in a region close to the interface with overlying doped layer 110 and/or the multiplication layer 106 (or charge layer 207 in FIG. 2). Graded interlayers and doping can reduce potential barriers for charge carriers, as well as improve carrier extraction from the active (absorbing) layer.

The multiplication layer 106 can comprise a p-type III-V layer that amplifies the current generated by the active layer 108 through avalanche multiplication. Thus, for each free carrier (electron or hole) generated by the active layer 108, the multiplication layer 106 generates one or more carriers via the avalanche effect. Thus, the multiplication layer 106 increases the total current generated by the semiconductor 100. Multiplication layer 106 can comprise a III-V material, such as GaAs, or AlGaAs, AlInGaP, or a dilute nitride such as GaInNAsSb, comprising Ga₁₋ₓInₓN_{y}As_{1-y-z}Sb_{z}, where x, y and z can be 0≤x≤0.4, 0≤y≤0.07 and 0<z≤0.2. As will be explained, multiplication layer 106 can comprise more than one layer with more than one composition, or with a graded composition in order to improve the optoelectronic performance of the device. Multiplication layer 106 can comprise an intrinsic layer or an unintentionally doped layer. Unintentionally doped semiconductors do not have dopants intentionally added but can include a nonzero concentration of impurities that act as dopants. The carrier concentration of the multiplication layer can be, for example, less than 1×10¹⁶ cm⁻³ (measured at room temperature), less than 5×10¹⁵ cm⁻³, or less than 1×10¹⁵ cm⁻³. However, multiplication layer 106 can be doped close to the interface with overlying active layer 110 (or charge layer 207 in FIG. 2), and/or the underlying first doped layer 104. The thickness of multiplication layer 106 can be within a range from 0.05 μm to 1.5 μm.

FIG. 2 shows a side view of an example of a semiconductor optoelectronic device 200 according to the present invention. Device 200 is similar to device 100, but it has an additional charge layer 207 overlying the multiplication layer 206 and underlying active layer 208. A narrower bandgap dilute nitride material as the active layer 208 can produce more dark current under operation, since a high field required for multiplication can also cause tunneling between bands. Charge layer 207 has a larger bandgap than active layer 208 and is also doped to control the potential across the absorption material, so that only the multiplication layer experiences a very high electric field. Charge layer 207 can comprise a III-V material that has a larger bandgap than active layer 206, such as GaAs, or AlGaAs, AlInGaP, or a dilute nitride such as Ga₁₋ₓInₓN_{y}As_{1-y-z}Sb_{z}, where x, y and z can be 0≤x≤0.4, 0≤y≤0.07 and 0<z≤0.2, or where x, y and z can be 0≤x≤0.4, 0≤y≤0.07 and 0<z≤0.04. The thickness of charge layer 207 and the doping level of charge layer 207 provide a total charge in the charge layer. The total charge can be chosen to minimize the field across active layer 208 when the APD is operating at a high electric field close to the breakdown condition for the multiplication layer 206, while ensuring the field across absorption layer 208 is strong enough for efficient collection of photogenerated charge carriers. The total charge of charge layer 207 also ensures that the “punch-through” operating condition, i.e., the bias at which the depletion region reaches the absorption layer, occurs at a suitable voltage or field that allows the onset of amplification. The thickness of charge layer 207 can be within a range, for example, from 0.1 μm to 1 μm. The doping level of charge layer 207 can be between 1×10¹⁷ cm⁻¹ and 5×10¹⁸ cm⁻³.

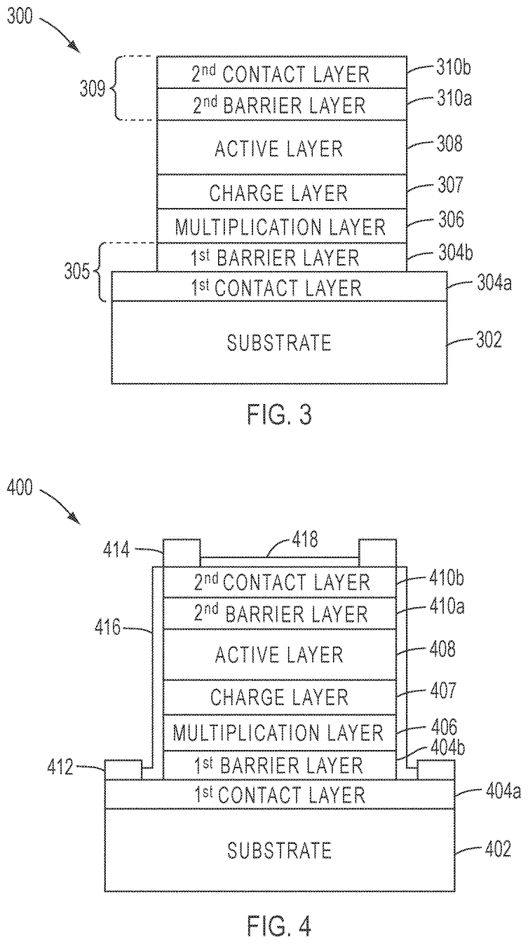

FIG. 3 shows a side view of an example of a semiconductor optoelectronic device 300 according to the present invention. Device 300 is similar to device 200, but each of the doped layers are shown to comprise two layers. Device 300 includes a substrate 302, a first contact layer 304a, a first barrier layer 304b, a multiplication layer 306, a charge layer 307, an active layer 308, a second barrier layer 310a, and a second contact layer 310b.

Substrate 302 can have a lattice constant that matches or nearly matches the lattice constant of GaAs or Ge. The substrate can be GaAs. Substrate 302 may be doped p-type, or n-type, or may be a semi-insulating (SI) substrate. The thickness of substrate 302 can be chosen to be any suitable thickness. Substrate 302 can include one or more layers, for example, substrate 302 can include a Si layer having an overlying SiGeSn buffer layer that is engineered to have a lattice constant that matches or nearly matches the lattice constant of GaAs or Ge. This can mean the substrate can have a lattice parameter different than that of GaAs or Ge by less than or equal to 3%, less than 1%, or less than 0.5% of GaAs or Ge.

First contact layer 304a and first barrier layer 304b provide a first doped layer 305, having a doping of one type, and second barrier layer 310a and second contact layer 310b provide a second doped layer 309, having a doping of the opposite type. If first doped layer 305 is doped n-type, second doped layer 309 is doped p-type. Conversely, if first doped layer 305 is doped p-type, second doped layer 309 is doped n-type. Examples of p-type dopants include C and Be. Examples of n-type dopants include Si and Te. Doped layers 305 and 309 can be chosen to have a composition that is lattice matched or pseudomorphically strained to the substrate. The doped layers can comprise any suitable III-V material, such as, for example, GaAs, AlGaAs, GaInAs, GaInP, GaInPAs, GaInNAs, GaInNAsSb. The contact and barrier layers can have different compositions and different thicknesses. The bandgap of the doped layers can be selected to be larger than the bandgap of active region 306. The doping level of first contact layer 304a can be chosen to be higher than the doping level of first barrier layer 304b. A higher doping facilitates electrical connection with a metal contact. Similarly, the doping level of second contact layer 310b can be chosen to be higher than the doping level of second barrier layer 310a. Higher doping levels facilitate electrical connection with a metal contact. Doping levels can be, for example, within a range from 1×10¹⁵ cm⁻³ to 2×10¹⁹ cm⁻³. Doping levels may be constant within a layer and/or the doping profile may be graded, for example, increasing the doping level from a minimum value to a maximum value as a function of the distance from the interface between the doped layer and the active layer. Each of layers 304a, 304b, 310a and 310b can have a thickness, for example, within a range from 50 nm to 3 μm.

The multiplication layer 306 can comprise a p-type III-V layer that amplifies the current generated by the active layer 308 through avalanche multiplication. Thus, for each free carrier (electron or hole) generated by the active layer 308, the multiplication layer 306 generates one or more carriers via the avalanche effect. Thus, the multiplication layer 306 increases the total current generated by the semiconductor 300. Multiplication layer 306 can comprise a III-V material, such as GaAs, or AlGaAs, AlInGaP, or a dilute nitride such as Ga₁₋ₓInₓN_{y}As_{1-y-z}Sb_{z}, where x, y and z can be 0≤x≤0.4, 0≤y≤0.07 and 0<z≤0.2. As will be explained, multiplication layer 306 can comprise more than one layer with a different composition, or with a graded composition in order to improve the optoelectronic performance of the device. Multiplication layer 306 can comprise an intrinsic layer or an unintentionally doped layer. Unintentionally doped semiconductors do not have dopants intentionally added but can include a nonzero concentration of impurities that act as dopants. The carrier concentration of the multiplication layer 306 can be, for example, less than 1×10¹⁶ cm⁻³ (measured at room temperature), less than 5×10¹⁵ cm⁻³, or less than 1×10¹⁵ cm⁻³. However, multiplication layer 306 can be doped close to the interface with overlying charge layer 307, and/or the underlying first barrier layer 304b. The thickness of multiplication layer 306 can be within a range from 0.05 μm to 1.5 μm.

Charge layer 307 can be a doped III-V layer has a larger bandgap than active layer 308 and is also doped to control the potential across the absorption material, so that only the multiplication layer 306 experiences a very high electric field. Charge layer 307 can comprise a III-V material that has a larger bandgap than active layer 306, such as GaAs, or AlGaAs, AlInGaP, or a dilute nitride such as Ga₁₋ₓInₓN_{y}As_{1-y-z}Sb_{z}, where x, y and z can be 0≤x≤0.4, 0≤y≤0.07 and 0<z≤0.2, or where x, y and z can be 0≤x≤0.4, 0≤y≤0.07 and 0<z≤0.04. The thickness of charge layer 307 and the doping level of charge layer 307 provide a total charge in the charge layer. The total charge can be chosen to minimize the field across active layer 308 when the APD is operating at a high electric field close to the breakdown condition for the multiplication layer 306, while ensuring the field across absorption layer 308 is strong enough for efficient collection of photogenerated charge carriers. The total charge of charge layer 307 also ensures that the “punch-through” operating condition, the bias at which the depletion region reaches the absorption layer, occurs at a suitable voltage or field that allows the onset of amplification. The thickness of charge layer 307 can be within a range from 0.1 μm to 1 μm. The doping level of charge layer 307 can be between 1×10¹′ cm⁻³ and 5×10¹⁸ cm⁻³.

Active layer 308 can be lattice matched or pseudomorphically strained with respect to the substrate and/or to the doped layers. The bandgap of active layer 308 can be lower than that of layers 304a, 304b, 310a and 310b. Active layer 308 can comprise a layer capable of processing light over a desired wavelength range. Processing is defined to be a light emission, a light receiving, a light sensing and light modulation. Active layer 308 can include a dilute nitride material. The dilute nitride material can be Ga₁₋ₓInₓN_{y}As_{1-y-z}Sb_{z}, where x, y and z can be 0≤x≤0.4, 0≤y≤0.07 and 0<z≤0.2, respectively. In some embodiments, x, y and z can be 0.01≤x≤0.4, 0.02≤y≤0.07 and 0.001≤z≤0.04, respectively. Active layer 308 can have a bandgap within a range from 0.7 eV to 1.2 eV such that the active layer can absorb or emit light at wavelengths up to 1.8 μm. Bismuth (Bi) may be added as a surfactant during growth of the dilute nitride, improving material quality (such as defect density), and the device performance. The thickness of active layer 308 can be, for example, within a range from 0.2 μm to 10 μm or from 1 μm to 4 μm. Active layer 308 can be an intrinsic layer or an unintentionally doped layer. Unintentionally doped semiconductors do not have dopants intentionally added but can include a non-zero concentration of impurities that act as dopants. The carrier concentration of the active layer 308 can be, for example, less than 1×10¹⁶ cm⁻¹ (measured at room temperature), less than 5×10¹⁵ cm⁻³, or less than 1×10¹⁵ cm⁻³. However, active layer 308 can be doped close to the interface with overlying second barrier layer 310a and/or the underlying charge layer 307. The composition of active layer 308 can also be increased in a region close to the interface with overlying second barrier layer 310a and/or the underlying charge layer 307 in FIG. 2. Active layer 308 can be compressively strained with respect to the substrate 302. Strain can also improve device performance. For a photodetector, the parameters most relevant to device performance include the dark current, operating speed, noise and responsivity.

FIG. 4 Shows a side view of an example of a photodetector 400 according to the present invention. Device 400 is similar to device 300. Compared to device 300, additional device layers include a first metal contact 412, a second metal contact 414, a passivation layer 416, and an antireflection coating 418. The semiconductor layers 402, 404a, 404b, 406, 407, 408, 410a and 410b correspond to layers 302, 304a, 304b, 306, 307, 308, 310a and 310b of device 300, respectively. Multiple lithography and materials deposition steps may be used to form the metal contacts, passivation layer, and antireflection coating. The device structure has a mesa structure, produced by etching. This exposes the underlying layers. A passivation layer 416 is provided that covers the side-walls of the device and exposed surfaces of the semiconductor layers so as to reduce effects of surface defects and dangling bonds that may otherwise affect device performance. The passivation layer can be formed using a dielectric material such as silicon nitride, silicon oxide, or titanium oxide. Anti-reflection layer 418 overlies a first portion of second contact layer 410b. The antireflection layer 418 can be formed using a dielectric material such as silicon nitride, silicon oxide, or titanium oxide. A first metal contact 412 overlies a portion of the first contact layer 404a. A second metal contact 410b overlies a portion of second barrier layer 410a. Metallization schemes for contacting to n-doped and p-doped materials are known to those ordinarily skilled in the art. Exemplary photodetector 400 is illuminated from the top surface of the device, i.e. through the interface between anti-reflection coating 418 and air.

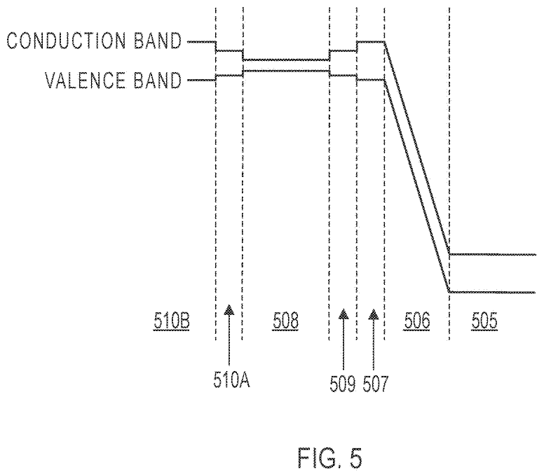

FIG. 5 shows a schematic band edge diagram for an avalanche photodetector with separate absorber, charge and multiplication layers, in accordance with the present invention. The conduction band and the valence band are both shown. The semiconductor layers 505, 506, 507, 508, 510a and 510b correspond to layers 302, 305 306, 307, 308, 310a and 310b of device 300 in FIG. 3, respectively. Additionally, a grading layer 509 overlies charge layer 507 and underlies active layer 508. Grading layer 509 comprises Ga₁₋ₓInₓN_{y}As_{1-y-z}Sb_{z}, where x, y and z can be 0≤x≤0.4, 0≤y≤0.07 and 0<z≤0.2, respectively. In some embodiments, x, y and z can be 0.01≤x≤0.4, 0.02≤y≤0.07 and 0.001≤z≤0.04, respectively. Grading layer 509 can have a larger bandgap than active layer 508 and a bandgap less than or equal to the bandgap of charge layer 507. Grading layer 509 and can have a fixed composition, or a composition that increases the bandgap from the interface with absorbing layer 508 and charge layer 507. Grading layer 509 can also be doped. Grading layer 509 can facilitate extraction of the photogenerated carriers from active layer 508. The conduction and valence bands for active layer 508 are shown as flat. However, active layer 508 can have a background carrier concentration, for example, less than 1×10¹⁶ cm⁻³ (measured at room temperature (23° C.)), less than 5×10¹⁵ cm⁻³, or less than 1×10¹⁵ cm⁻³, which can introduce a small tilt the band edges in practical devices.

In embodiments shown, the charge layer is a separate layer from the active layer and the multiplication layer. In some embodiments, the charge layer can be formed close to the interface between the multiplication layer and the active layer and/or grading layer. The charge layer can be formed, for example by composition and/or doping grades at the active layer and/or grading layer proximate to the multiplication layer.

In one example, APDs with an absorbing layer of GaInNAsSb and an AlGaAs multiplication layer can be fabricated on a GaAs substrate. The multiplication layer can be a low noise Al_{0.80}Ga_{0.20}As multiplication layer or a superlattice structure, such as GaAs/AlGaAs. A charge layer can be used between the narrow bandgap absorber and the multiplication layer. The thickness and doping levels for the avalanche region of the photodetector can be chosen based on desired device operating parameters including the desired multiplication (gain), frequency bandwidth, and operating voltage. Using MOCVD growth, a first contact layer of GaAs can be formed on an underlying substrate, having a thickness between 0.5 μm and 1 μm, and a n-type doping level between 1×10¹⁸ cm⁻³ and 5×10¹⁸ cm⁻³. The first barrier layer overlies the first contact layer and is a n-doped Al_{0.80}Ga_{0.20}As layer with a thickness between 0.1 μm and 0.2 μm, and a doping level of 1×10¹⁸ cm⁻³. An undoped Al_{0.80}Ga_{0.20}As layer with a thickness between 50 nm and 1.5 μm (and preferably between 50 nm and 200 nm) forms the multiplication layer and overlies the first barrier layer. A p-doped Al_{0.80}Ga_{0.20}As layer with a thickness between 50 nm and 250 nm and a doping level between 1×10¹⁷ cm⁻³ and 1×10¹⁸ cm⁻³ overlies the multiplication layer. This is optionally capped by a GaAs layer between 1 nm and 10 nm thick, and having a doping level between 1×10¹⁷ cm⁻³ and 1×10¹⁸ cm⁻³. The p-doped AlGaAs layer and optional GaAs cap form the charge layer. In an alternative embodiment, p-doped InGaP can be used to form the charge layer. After growth of at least a portion of the charge layer (including any GaAs cap), the epiwafer is transferred to an MBE chamber for subsequent growth of the dilute nitride absorber layer. The GaAs layer is completed (as required) before an undoped GaInNAsSb active layer is formed overlying the charge layer, having a thickness within a range from 0.5 μm to 1.5 μm. The second barrier layer is a p-doped GaAs layer with a thickness between 0.1 μm and 0.2 μm, and a doping level of 1×10¹⁸ cm⁻³. The second contact layer is a p-doped GaAs layer with a thickness between 50 nm and 100 nm and a doping level of between 1×10¹⁸ cm⁻³ and 1×10¹⁹ cm⁻³. The strain of the dilute nitride layer can be characterized using high-resolution X-ray diffraction (XRD). The layer can exhibit a peak splitting between the substrate and dilute nitride layer in the within a range from −600 arcsec to −1000 arcsec, corresponding to a compressive strain of 0.2% to 0.35%. Devices with active (absorbing) layers with compressive strain up to 0.4% are also possible.

A multiplication layer can comprise a single layer or can comprise two or more interlayers. The material composition within a multiplication layer or interlayer can be constant across the thickness of the layer or interlayer or can vary across the thickness of the layer or interlayer. Similarly, the bandgap within a multiplication layer or interlayer can be constant across the thickness of the layer or interlayer or can vary across the thickness of the layer or interlayer. For example, the material composition and bandgap across the thickness of a layer or interlayer can vary linearly. The bandgap within a linearly graded layer or interlayer can have a minimum bandgap and a maximum bandgap. For example, the minimum bandgap can be within a range from 0.7 eV to 1.3 eV, and the maximum bandgap can be within a range from 0.8 eV to 1.42 eV. The difference between the minimum bandgap and the maximum bandgap can be, for example, from 100 meV to 600 meV, from 400 meV to 600 meV, or from 200 meV to 500 meV.

A multiplication layer can comprise one or more interlayers. Each of the one or more interlayers can independently comprise Ga₁₋ₓInₓN_{y}As_{1-y-z}(Sb,Bi)_{z}. Each of the one or more interlayers can have a material composition and bandgap that is substantially constant across the thickness of the interlayer. A multiplication layer comprising two or more interlayers can be characterized by an interlayer having a minimum bandgap, and an interlayer having a maximum bandgap. For example, the minimum bandgap can be within a range from 0.7 eV to 1.3 eV, and the maximum bandgap can be within a range from 0.8 eV to 1.42 eV. The difference between the minimum bandgap and the maximum bandgap can be, for example, from 100 meV to 600 meV, from 400 meV to 600 meV, or from 200 meV to 500 meV.

A multiplication layer can comprise one or more interlayers. Each of the one or more interlayers can independently comprise Ga₁₋ₓInₓN_{y}As_{1-y-z}(Sb,Bi)_{z}. Each of the one or more interlayers can have a material composition and bandgap that is linearly graded across the thickness of the interlayer. A multiplication layer comprising two or more interlayers can be characterized by an interlayer having a minimum bandgap, and an interlayer having a maximum bandgap. For example, the minimum bandgap can be within a range from 0.7 eV to 1.3 eV, and the maximum bandgap can be within a range from 0.8 eV to 1.42 eV. The difference between the minimum bandgap and the maximum bandgap can be, for example, from 100 meV to 600 meV, from 400 meV to 600 meV, or from 200 meV to 500 meV.

A multiplication layer can comprise one or more interlayers having a constant bandgap, one or more interlayers having a linearly graded bandgap, or a combination thereof.

In another example, APDs with an active layer of GaInNAsSb and a GaInNAsSb multiplication layer can be fabricated on a GaAs substrate. A first contact layer of GaAs or AlGaAs can be formed overlying the substrate having a thickness between 0.5 μm and 1 μm, and a n-type doping level between 1×10¹⁸ cm⁻¹ and 5×10¹⁸ cm⁻³. The first barrier layer overlies the first contact layer and is a n-doped GaInNAsSb layer with a thickness between 0.1 μm and 0.2 μm, and a doping level between 1×10¹⁸ cm⁻³ and 2×10¹⁸ cm⁻³. An undoped GaInNAsSb layer with a thickness between 50 nm and 1 μm (and preferably between 50 nm and 200 nm) forms the multiplication layer and overlies the first barrier layer. A p-doped GaInNAsSb layer with a thickness between 50 nm and 250 nm and a doping level between 1×10¹⁷ cm⁻³ and 1×10¹⁸ cm⁻³ overlies the multiplication layer and forms the charge layer. The bandgap of the charge layer is larger than the bandgap of the overlying active layer. In some embodiments, the charge layer comprises Ga₁₋ₓInₓN_{y}As_{1-y-z}Sb_{z}, where x, y and z can be 0≤x≤0.4, 0≤y≤0.07 and 0<z≤0.2, respectively. In some embodiments, the charge layer comprises GaNᵥAs_{1-v-w}Sb_{w}, where 0≤v≤0.03 and 0≤w≤0.1. In some embodiments, the charge layer comprises AlInGaP or InGaP, lattice matched or pseudomorphically strained to the substrate. An undoped GaInNAsSb active (or absorber) layer is formed overlying the charge layer, having a thickness within a range from 0.5 μm to 1.5 μm. The second barrier layer overlies the active layer and is a p-doped GaAs or AlGaAs layer with a thickness between 0.1 μm and 0.2 μm, and a doping level of 1×10¹⁸ cm⁻³. The second contact layer is a p-doped GaAs or AlGaAs layer with a thickness between 50 nm and 100 nm and a doping level of between 1×10¹⁸ cm⁻³ and 1×10¹⁹ cm⁻³. The strain of the dilute nitride layer can be characterized using high-resolution X-ray diffraction (XRD). The layer can exhibit a peak splitting between the substrate and dilute nitride layer in the within a range from −600 arcsec to −1000 arcsec, corresponding to a compressive strain of 0.2% to 0.35%. Devices with active (absorbing) layers with compressive strain up to 0.4% are also possible.

In another example, a dilute nitride multiplication layer can be used that has a step-like or graded band structure, having multiple layers with different compositions. While the gain provided by an APD can provide higher sensitivity than p-i-n photodiodes, the noise performance of the detector is also important. Multiplication can result in excess noise related to the stochastic or statistical nature of the avalanche (or impact ionization) process. The excess noise factor F(M) is a function of the carrier ionization ratio, k, where k is usually defined as the ratio of hole to electron ionization probabilities (k≤1). In a conventional APD, impact ionization can occur relatively uniformly across the multiplication layer. Alternative multiplication regions for APDs, such as staircase APDs have been proposed in other material systems as one way to achieve low noise and make use of bandgap discontinuities that cause the avalanche process to occur proximate to sudden bandgap changes. As electrons in a wider bandgap region move into a narrower bandgap region, their excess energy enables immediate impact ionization. As a result, the gain process is more deterministic, which can reduce gain fluctuations and reduce excess noise. However, the AlGaAs material system has inadequate band offsets, with approximately 60% of the band offset between GaAs and AlGaAs accommodated in the conduction band (i.e., the conduction band offset) and approximately 40% accommodated in the valence band (i.e., the valence band offset). Impact ionization can occur for both electrons and holes, which can lead to increased noise. Furthermore, the material changes from having a direct bandgap to having an indirect bandgap for alloy compositions with an Al fraction (of group III atoms) of about 45%, limiting the maximum band offset. Consequently, it is difficult to achieve reduced noise characteristics. The use of dilute nitride materials such as GaInNAsSb, GaInNAs, GaInNAsSbBi and GaInNAsBi, lattice matched or pseudomorphically strained with respect to a substrate can allow larger bandgap changes without a transition from a direct to indirect bandgap, and with larger conduction band offsets than achievable with AlGaAs materials. The inclusion of nitrogen in the alloy introduces a significant bandgap bowing that reduces the bandgap of the dilute nitride material, which, in addition to the inclusion of indium in the alloy, introduces a larger fraction of the band offset in the conduction band (increasing the conduction band offset ratio) and reduces the valence band offset ratio. The larger difference between the conduction band offset and the valence band offset can enhance the ionization ratio asymmetry between electrons and holes. Dilute nitride materials can therefore be used to improve the noise performance of staircase and other graded composition avalanche regions of APDs grown on GaAs substrates.

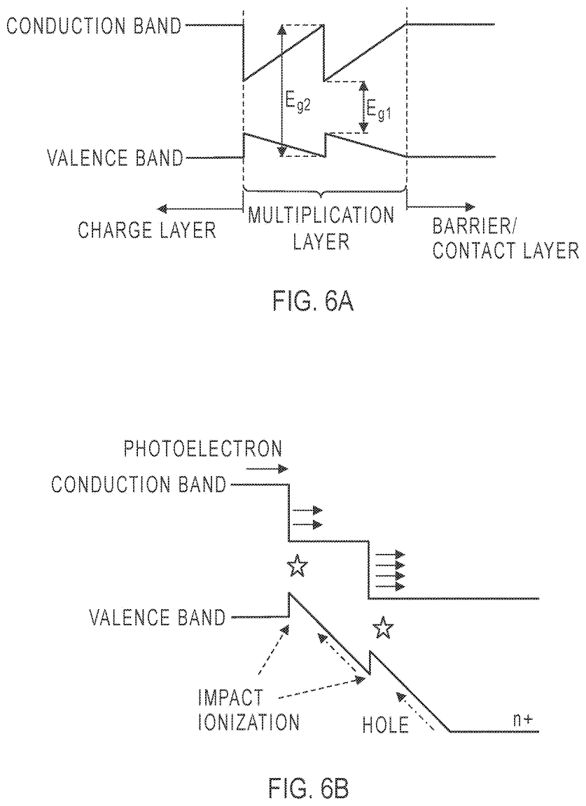

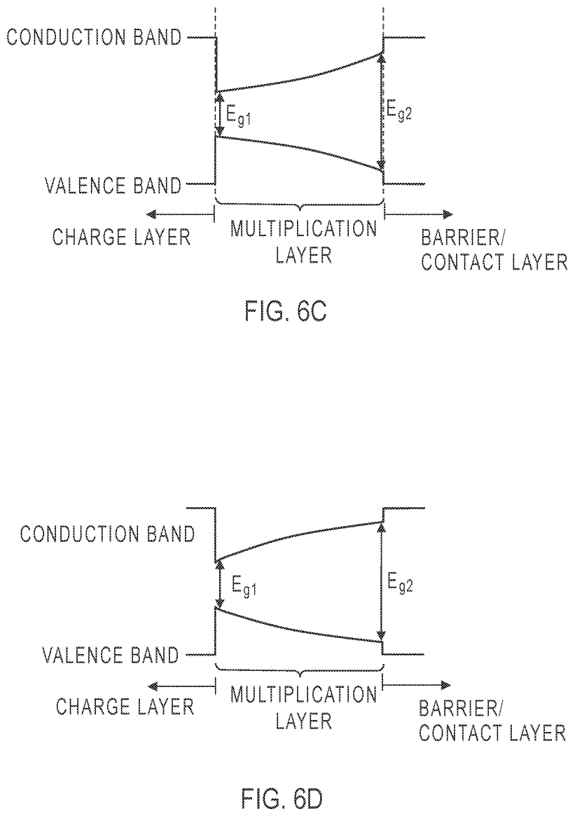

FIG. 6A and FIG. 6B show band edge diagrams for a staircase multiplication region having a continuously graded composition at zero bias and under reverse bias, respectively. By way of example, two graded regions are shown, each graded region having a linearly graded bandgap. However, different numbers of graded regions may be used and different graded bandgap profiles may also be used, such as a non-linearly graded bandgap as shown in FIGS. 6C and 6D. The multiplication region can comprise at least one graded region overlying the first barrier and contact layers and underlying the charge layer. As a photogenerated electron, created by absorption of a photon in the absorbing layer, moves from the wide bandgap region (with bandgap E_{g2}) into the narrow bandgap region (with bandgap E_{g1}), the excess energy enables immediate impact ionization to occur. The graded region then allows the carriers to move across to the next bandgap discontinuity at which impact ionization next occurs. The material forming the largest bandgap region can comprise Ga₁₋ₚInₚN_{q}As_{1-q-r}Sbᵣ, where p, q and r can be 0≤p≤0.4, 0≤q≤0.07 and 0<r≤0.2, respectively. In some embodiments, the largest bandgap region can comprise an In-free material GaNᵥAs_{1-v-w}Sb_{w}, where 0≤v≤0.03 and 0≤w≤0.1, or can comprise GaAs. The material forming the narrowest bandgap comprises Ga₁₋ₓInₓN_{y}As_{1-y-z}Sb_{z}, where x, y and z can be 0≤x≤0.4, 0≤y≤0.07 and 0<z≤0.2, respectively. In some embodiments, x, y and z can be 0.01≤x≤0.4, 0.02≤y≤0.07 and 0.001≤z≤0.04, respectively. The addition of Sb in the widest bandgap material causes the valence band to shift upwards faster than any shift in the conduction band and can therefore reduce the portion of the bandgap offset in the valance band and increase the portion of the bandgap offset in the conduction band, at the interface with the narrower bandgap material. In some embodiments, the bandgap difference between E_{g1} and E_{g2} can be about 600 meV. In some embodiments, the bandgap difference can be between 100 meV and 500 meV, or can be between 200 meV and 400 meV. The thickness of a graded region can be between 50 nm and 500 nm, and more than one graded region may be used to form the multiplication region.

Practically, growing a dilute nitride material with a linearly graded bandgap can be challenging, requiring controlled changes in growth rates, and/or growth temperature to modify the N-incorporation. During the growth of a graded dilute nitride material, the flux ratio of the effusion cells can be changed linearly between the values required for the beginning composition and the end composition. This can be achieved for example, by changing the Ga flux during growth. By lowering the Ga flux, while leaving the In, As, Sb and N fluxes the same, the In/Ga ratio is increased during growth due to the changed group-III flux ratio. The N/As ratio also increases due to the lower growth rate and the near-unity sticking coefficient for N. The increasing In and N fractions in the semiconductor alloy allow a decrease in the material bandgap while also keeping the lattice constant relatively close to that of GaAs.

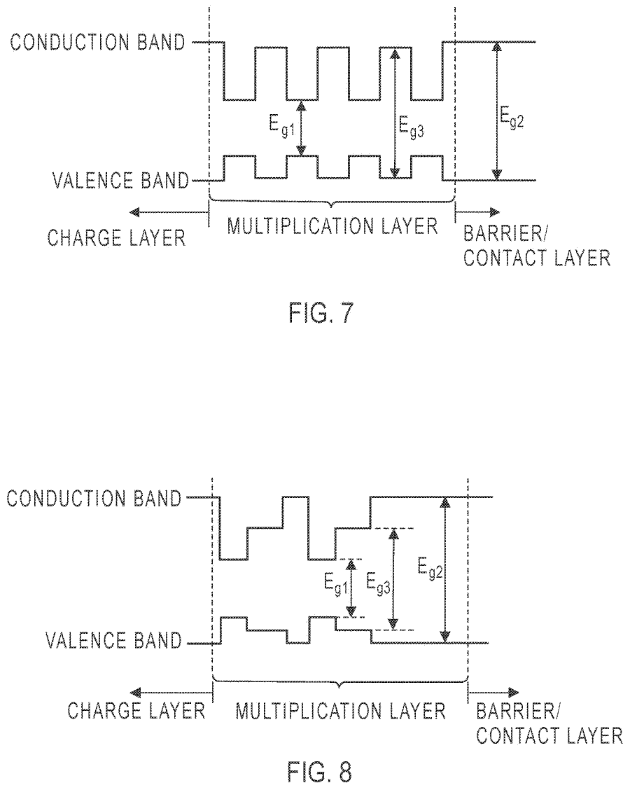

An alternative design to a continuously graded bandgap profile, such as a linearly graded bandgap profile or a non-linearly graded bandgap profile, is a superlattice design, using alternating thin layers with different bandgaps and compositions. This is shown in FIG. 7, where the multiplication region comprises at least one superlattice structure overlying the first barrier and contact layers and underlying the charge layer. The bandgap of the charge layer and the underlying barrier/contact layer is shown to have a bandgap E_{g2}. In the multiplication layer, the widest bandgap material comprises Ga₁₋ₚInₚN_{q}As_{1-q-r}Sbᵣ, where p, q and r can be 0≤p≤0.4, 0≤q≤0.07 and 0<r≤0.2, respectively, and has a bandgap E_{g3} which may be equal to or lesser than E. In some embodiments, the largest bandgap region of the multiplication layer can comprise an In-free material GaNᵥAs_{1-v-w}Sb_{w}, where 0≤v≤0.03 and 0≤w≤0.1, or can comprise GaAs. The material forming the narrowest bandgap comprises Ga₁₋ₓInₓN_{y}As_{1-y-z}Sb_{z}, where x, y and z can be 0≤x≤0.4, 0<y≤0.07 and 0<z≤0.2, respectively, and has a bandgap E_{g1} less than E_{g2}. In some embodiments, x, y and z can be 0.01≤x≤0.4, 0.02≤y≤0.07 and 0.001≤z≤0.04, respectively. These layers form a superlattice. The inclusion of Sb in widest bandgap material causes valence band to shift upwards faster than conduction band and can therefore reduce the portion of the bandgap offset in the valance band and increase the portion of the bandgap offset in the conduction band. In some embodiments, the bandgap difference between E_{g1} and E_{g3} can be about 600 meV. In some embodiments, the bandgap difference can be between 100 meV and 500 meV, or can be between 200 meV and 400 meV. The thickness of each superlattice layer, independently, can be, for example, between 10 nm and 200 nm. A growth pause can be implemented at each composition step change within the superlattice. A composition gradient can exist at each composition step within the structure, which can assist in carrier transport across the heterostructures.

In some embodiments, the superlattice design can have a transition from the narrow bandgap material to the wide bandgap material, which can be achieved through several steps with different compositions and bandgaps. This can assist with carrier transport and help reduce trapping in well-like regions. A design example is shown in FIG. 8. In this example the wide bandgap material has a bandgap E_{g2}, the narrow bandgap material has a bandgap E_{g1}, and an intermediate step layer between the wide and narrow bandgap materials has a bandgap E_{g3} between E_{g1} and E_{g2}. In this example, a single step is shown. However, it will be understood that multiple steps can also be used, each step having a different bandgap intermediate between E_{g1} and E_{g2}, with the bandgaps of the steps arranged in increasing bandgap order between E_{g1} and E_{g2}. For example, a second step may have a bandgap E_{g4}. A stepped structure can be used to approximate a linear grade, as shown in FIGS. 6A and 6B. The bandgap difference between E_{g1} and E_{g2} can be, for example, between 100 meV and 600 meV, or can be between 200 meV and 400 meV. The thickness of each superlattice layer, independently, can be between 10 nm and 200 nm. Growth pauses can be implemented at each composition step change. The bandgap step size can be chosen based on the number of steps and the bandgap difference between E_{g1} and E_{g2}. In some embodiments, the bandgap step size between adjacent layers is approximately the same. A composition gradient can exist at each composition step within the structure, which can assist in carrier transport across the heterostructures.

The charge layer overlies the multiplication layer and can comprise Ga₁₋ₓInₓN_{y}As_{1-y-z}Sb_{z}, where x, y and z can be 0≤x≤0.4, 0≤y≤0.07 and 0≤z≤0.2, respectively. In some embodiments, the charge layer comprises GaNᵥAs_{1-v-w}Sb_{w}, where 0≤v≤0.03 and 0≤w≤0.1. In some embodiments, the charge layer comprises AlGaAs, AlInGaP or InGaP lattice matched or pseudomorphically strained to the substrate.

In devices provided the present disclosure, the dilute nitride layer can have a minority carrier lifetime, for example, of 1 ns or greater, greater than 1 ns, from 1.1 ns to 4 ns, from 1.1 ns to 3 ns, or from 1.1 ns to 2.5 ns, measured at an excitation wavelength of 970 nm, with an average CW power of 0.250 mW, and a pulse duration of 200 fs at a repetition rate of 250 kHz generated by a Ti:Sapphire:OPA laser.

To fabricate optoelectronic devices provided by the present disclosure, a plurality of layers is deposited on a substrate in at least one materials deposition chamber. The plurality of layers may include active layers, doped layers, contact layers, etch stop layers, release layers, i.e., layers designed to release the semiconductor layers from the substrate when a specific process sequence, such as chemical etching, is applied, buffer layers, or other semiconductor layers.

The plurality of layers can be deposited by molecular beam epitaxy (MBE) or by metal-organic chemical vapor deposition (MOCVD). Combinations of deposition methods may also be used.

A semiconductor optoelectronic device can be subjected to one or more thermal annealing treatments after growth. For example, a thermal annealing treatment can include the application of a temperature of 400° C. to 1000° C. for from 10 seconds to 10 hours. Thermal annealing may be performed in an atmosphere that includes air, nitrogen, arsenic, arsine, phosphorus, phosphine, hydrogen, forming gas, oxygen, helium and any combination of the preceding materials.

### ASPECTS OF THE INVENTION

The invention is further defined by the following aspects.

Aspect 1. A semiconductor optoelectronic device, comprising: a substrate; a first barrier layer overlying the substrate; a multiplication layer overlying the first barrier layer; wherein the multiplication layer comprises Ga₁₋ₓInₓN_{y}As_{1-y-z}(Sb,Bi)_{z}, wherein 0≤x≤0.4, 0≤y≤0.07, and 0≤z≤0.2, an active layer overlying the multiplication layer, wherein, the active layer comprises a lattice matched or pseudomorphic dilute nitride material; and the dilute nitride material has a bandgap within a range from 0.7 eV and 1.2 eV; and a second barrier layer overlying the active layer.

Aspect 2. The device of aspect 1, wherein each of the first barrier layer and the second barrier layer independently comprises a doped III-V material.

Aspect 3. The device of any one of aspects 1 to 2, wherein the substrate comprises GaAs, AlGaAs, Ge, SiGeSn, or buffered Si.

Aspect 4. The device of any one of aspects 1 to 3, further comprising a charge layer overlying the multiplication layer and underlying the active layer.

Aspect 5. The device of any one of aspects 1 to 4, wherein the active layer has a compressive strain within a range from 0% and 0.4%.

Aspect 6. The device of any one of aspects 1 to 5, wherein the active layer has a minority carrier lifetime of 1 ns or greater, measured at an excitation wavelength of 970 nm, with an average CW power of 0.250 mW, and a pulse duration of 200 fs at a repetition rate of 250 kHz generated by a Ti:Sapphire:OPA laser.

Aspect 7. The device of any one of aspects 1 to 6, wherein the active layer has a lattice constant substantially the same as the lattice constant of GaAs or Ge.

Aspect 8. The device of any one of aspects 1 to 7, wherein the active layer comprises GaInNAs, GaNAsSb, GaInNAsSb, GaInNAsBi, GaNAsSbBi, GaNAsBi, or GaInNAsSbBi.

Aspect 9. The device of any one of aspects 1 to 8, wherein the active layer comprises Ga₁₋ₓInₓN_{y}As_{1-y-z}(Sb,Bi)_{z}, wherein 0≤x≤0.4, 0<y≤0.07, and 0<z≤0.2.

Aspect 10. The device of any one of aspects 1 to 9, wherein the active layer has a thickness within a range from 0.2 μm to 10 μm.

Aspect 11. The device of any one of aspects 1 to 10, wherein the multiplication layer comprises a linearly graded bandgap across the thickness of the layer and is characterized by a minimum bandgap and a maximum bandgap.

Aspect 12. The device of aspect 11, wherein the minimum bandgap is within a range from 0.7 eV to 1.3 eV and the maximum bandgap is within a range from 0.8 eV to 1.42 eV.

Aspect 13. The device of any one of aspects 11 to 12, wherein the difference between the minimum bandgap and the maximum bandgap is from 100 meV to 600 meV.

Aspect 14. The device of any one of aspects 11 to 12, wherein the difference between the minimum bandgap and the maximum bandgap is from 400 meV to 600 meV.

Aspect 15. The device of any one of aspects 11 to 12, wherein the difference between the minimum bandgap and the maximum bandgap is from 200 meV to 500 meV.

Aspect 16. The device of any one of aspects 1 to 10, wherein, the multiplication layer comprises one or more interlayers wherein each of the interlayers comprises Ga₁₋ₓInₓN_{y}As_{1-y-z}(Sb,Bi)_{z}; and the multiplication layer is characterized by a minimum bandgap and a maximum bandgap.

Aspect 17. The device of aspect 16, wherein at least one or more interlayers has a linearly graded bandgap across the interlayer thickness.

Aspect 18. The device of any one of aspects 16 to 17, wherein the minimum bandgap is within a range from 0.7 eV to 1.3 eV and the maximum bandgap is within a range from 0.8 eV to 1.42 eV.

Aspect 19. The device of any one of aspects 16 to 18, wherein the difference between the minimum bandgap and the maximum bandgap is from 100 meV to 600 meV.

Aspect 20. The device of any one of aspects 16 to 18, wherein the difference between the minimum bandgap and the maximum bandgap is from 400 meV to 600 meV.

Aspect 21. The device of any one of aspects 16 to 18, wherein the difference between the minimum bandgap and the maximum bandgap is from 200 meV to 500 meV.

Aspect 22. The device of any one of aspects 16 to 21, wherein the Ga₁₋ₓInₓN_{y}As_{1-y-z}(Sb,Bi)_{z} composition of the linearly graded interlayer varies from 0≤x≤0.4, 0≤y≤0.07 and 0<z≤0.2, to 0≤x≤0.4, 0≤y≤0.07, and 0<z≤0.2.

Aspect 23. The device of any one of aspects 1 to 10, wherein, the multiplication layer comprises two or more interlayers; and at least one of the two or more interlayers comprises a constant bandgap across the thickness of the interlayer.

Aspect 24. The device of claim 23, wherein each of the two or more interlayers has a constant bandgap across the interlayer thickness.

Aspect 25. The device of any one of aspects 1 to 10, wherein the multiplication layer comprises: a first interlayer comprising a first Ga₁₋ₓ₁Inₓ₁N_{y1}As_{1-y1-z1}(Sb,Bi)_{z1} composition; and a second interlayer comprising a second Ga₁₋ₓ₂Inₓ₂N_{y2}As_{1-y2-z2}(Sb,Bi)_{z2} composition, wherein the first Ga₁₋ₓ₁Inₓ₁N_{y1}As_{1-y1-z1}(Sb,Bi)_{z1} composition is different than the second Ga₁₋ₓ₂Inₓ₂N_{y2}As_{1-y2-z2}(Sb,Bi)_{z2} composition; and wherein each of the first interlayer and the second interlayer have a constant bandgap across the thickness of the respective interlayer.

Aspect 26. The device of aspect 25, wherein, the first Ga₁₋ₓ₁Inₓ₁N_{y1}As_{1-y1-z1}(Sb,Bi)_{z1} composition has a first bandgap within a range from 0.7 eV to 1.3 eV; and the second Ga₁₋ₓ₂Inₓ₂N_{y2}As_{1-y2-z2}(Sb,Bi)_{z2} composition has a second bandgap within a range from 0.8 eV to 1.42 eV.

Aspect 27. The device of any one of aspects 25 to 26, wherein the difference between the first bandgap and the second bandgap is from 100 meV to 600 meV.

Aspect 28. The device of any one of aspects 25 to 26, wherein the difference between the first bandgap and the second bandgap is from 400 meV to 600 meV.

Aspect 29. The device of any one of aspects 25 to 26, wherein the difference between the first bandgap and the second bandgap is from 200 meV to 500 meV.

Aspect 30. The device of any one of aspects 25 to 29, wherein, the first Ga₁₋ₓ₁Inₓ₁N_{y1}As_{1-y1-z1}(Sb,Bi)_{z1} composition is 0≤x1≤0.4, 0≤y1≤0.07 and 0<z1≤0.2; and the second Ga₁₋ₓ₂Inₓ₂N_{y2}As_{1-y2-z2}(Sb,Bi)_{z2} composition is 0≤x2≤0.4, 0≤y2≤0.07, and 0<z2≤0.2.

Aspect 31. The device of any one of aspects 1 to 10, wherein the multiplication layer comprises a superlattice structure.

Aspect 32. The device of aspect 31, wherein the superlattice comprises a stepped superlattice.

Aspect 33. The device of aspect 32, wherein the stepped superlattice comprises a periodic superlattice.

Aspect 34. The device of aspect 32, wherein the stepped superlattice comprises a staircase superlattice.

Aspect 35. The device of claim 31, wherein the superlattice comprises a linearly graded superlattice.

Aspect 36. The device of any one of aspects 1 to 35, wherein the device comprises an avalanche photodetector

Aspect 37. A method of forming a semiconductor optoelectronic device, comprising: forming a first barrier layer overlying a substrate; forming a multiplication layer overlying the first barrier layer, wherein the multiplication layer comprises Ga₁₋ₓInₓN_{y}As_{1-y-z}(Sb,Bi)_{z}, wherein 0≤x≤0.4, 0≤y≤0.07, and 0<z≤0.2; forming an active layer overlying the multiplication layer, wherein, the active layer comprises a pseudomorphic dilute nitride material; and the dilute nitride material has a bandgap within a range from 0.7 eV and 1.2 eV; and forming a second barrier layer overlying the active layer.

Aspect 38. The method of aspect 37, further comprising: after forming the multiplication layer, forming a charge layer overlying the multiplication layer; and forming the active layer comprises forming the active layer overlying the charge layer.

### EXAMPLES

To assess GaInNAsSb materials quality, GaInNAsSb layers were grown on undoped GaAs, with thicknesses within a range from 250 nm and 2 μm. The GaInNAsSb layers were capped with GaAs. Time-resolved photoluminescence (TRPL) measurements was performed to determine the minority carrier lifetime of the GaInNAsSb layer. The TRPL kinetics were measured at an excitation wavelength of 970 nm, with an average CW power of 0.250 mW, and a pulse duration of 200 fs generated by a Ti:Sapphire:OPA laser. The pulse repetition rate was 250 kHz. The laser beam diameter at the sample was approximately 1 mm. Whereas dilute nitride materials have been reported with minority carrier lifetimes below 1 ns, materials according to the present invention have higher carrier lifetime values, with carrier lifetimes between approximately 1.1 ns and 2.5 ns. Certain GaInNAsSb layers exhibited a minority carrier lifetime greater than 2 ns. Carrier lifetime can be affected by background doping levels and other defects that can be present in a material. The carrier lifetimes are therefore indicative of good materials quality, and can lead to improved performance of both absorber and multiplication layers of devices.

Finally, it should be noted that there are alternative ways of implementing the embodiments disclosed herein. Accordingly, the present embodiments are to be considered as illustrative and not restrictive. Furthermore, the claims are not to be limited to the details given herein, and are entitled their full scope and equivalents thereof.

1. A semiconductor optoelectronic device, comprising:
a substrate;
a first barrier layer overlying the substrate;
a multiplication layer overlying the first barrier layer;
wherein the multiplication layer comprises Ga₁₋ₓInₓN_{y}As_{1-y-z}(Sb,Bi)_{z}, wherein 0≤x≤0.4, 0≤y≤0.07, and 0≤z≤0.2.
an active layer overlying the multiplication layer, wherein,
the active layer comprises a lattice matched or pseudomorphic dilute nitride material; and
the dilute nitride material has a bandgap within a range from 0.7 eV and 1.2 eV; and
a second barrier layer overlying the active layer.

2. The device of claim 1, wherein each of the first barrier layer and the second barrier layer independently comprises a doped III-V material.

3. The device of claim 1, wherein the substrate comprises GaAs, AlGaAs, Ge, SiGeSn, or buffered Si.

4. The device of claim 1, further comprising a charge layer overlying the multiplication layer and underlying the active layer.

5. The device of claim 1, wherein the active layer comprises GaInNAs, GaNAsSb, GaInNAsSb, GaInNAsBi, GaNAsSbBi, GaNAsBi, or GaInNAsSbBi.

6. The device of claim 1, wherein the active layer comprises Ga₁₋ₓInₓN_{y}As_{1-y-z}(Sb,Bi)_{z}, wherein 0≤x≤0.4, 0<y≤0.07, and 0<z≤0.2.

7. The device of claim 1, wherein the multiplication layer comprises a linearly graded bandgap across the thickness of the layer and is characterized by a minimum bandgap and a maximum bandgap.

8. The device of claim 7, wherein the minimum bandgap is within a range from 0.7 eV to 1.3 eV and the maximum bandgap is within a range from 0.8 eV to 1.42 eV.

9. The device of claim 7, wherein the difference between the minimum bandgap and the maximum bandgap is from 100 meV to 600 meV.

10. The device of claim 1, wherein,
the multiplication layer comprises one or more interlayers wherein each of the interlayers comprises Ga₁₋ₓInₓN_{y}As_{1-y-z}(Sb,Bi)_{z}; and
the multiplication layer is characterized by a minimum bandgap and a maximum bandgap.

11. The device of claim 10, wherein at least one or more interlayers has a linearly graded bandgap across the interlayer thickness.

12. The device of claim 10, wherein the minimum bandgap is within a range from 0.7 eV to 1.3 eV and the maximum bandgap is within a range from 0.8 eV to 1.42 eV.

13. The device of claim 10, wherein the difference between the minimum bandgap and the maximum bandgap is from 100 meV to 600 meV.

14. The device of claim 10, wherein the Ga₁₋ₓInₓN_{y}As_{1-y-z}(Sb,Bi)_{z} composition of the linearly graded interlayer varies from 0≤x≤0.4, 0≤y≤0.07 and 0<z≤0.2, to 0≤x≤0.4, 0≤y≤0.07, and 0<z≤0.2.

15. The device of claim 1, wherein,
the multiplication layer comprises two or more interlayers; and
at least one of the two or more interlayers comprises a constant bandgap across the thickness of the interlayer.

16. The device of claim 15, wherein each of the two or more interlayers has a constant bandgap across the interlayer thickness.

17. The device of claim 1, wherein the multiplication layer comprises:
a first interlayer comprising a first Ga₁₋ₓ₁Inₓ₁N_{y1}As_{1-y1-z1}(Sb,Bi)_{z1} composition; and
a second interlayer comprising a second Ga₁₋ₓ₂In₂N_{y2}As_{1-y2-z2}(Sb,Bi)_{z2} composition,
wherein the first Ga₁₋ₓ₁Inₓ₁N_{y1}As_{1-y1-z1}(Sb,Bi)_{z1} composition is different than the second Ga₁₋ₓ₂Inₓ₂N_{y2}As_{1-y2-z2}(Sb,Bi)_{z2} composition; and
wherein each of the first interlayer and the second interlayer have a constant bandgap across the thickness of the respective interlayer.

18. The device of claim 17, wherein,
the first Ga₁₋ₓ₁Inₓ₁N_{y1}As_{1-y1-z1}(Sb,Bi)_{z1} composition has a first bandgap within a range from 0.7 eV to 1.3 eV; and
the second Ga₁₋ₓ₂Inₓ₂N_{y2}As_{1-y2-z2}(Sb,Bi)_{z2} composition has a second bandgap within a range from 0.8 eV to 1.42 eV.

19. The device of claim 18, wherein the difference between the first bandgap and the second bandgap is from 100 meV to 600 meV.

20. The device of claim 18, wherein,
the first Ga₁₋ₓ₁Inₓ₁N_{y1}As_{1-y1-z1}(Sb,Bi)_{z1} composition is 0≤x1≤0.4, 0≤y1≤0.07 and 0<z1≤0.2; and
the second Ga₁₋ₓ₂Inₓ₂N_{y2}As_{1-y2-z2}(Sb,Bi)_{z2} composition is 0≤x2≤0.4, 0≤y2≤0.07, and 0<z2≤0.2.

21. The device of claim 1, wherein the multiplication layer comprises a superlattice structure.

22. The device of claim 1, wherein the device comprises an avalanche photodetector

23. A method of forming a semiconductor optoelectronic device, comprising:
forming a first barrier layer overlying a substrate;
forming a multiplication layer overlying the first barrier layer, wherein the multiplication layer comprises Ga₁₋ₓInₓN_{y}As_{1-y-z}(Sb,Bi)_{z}, wherein 0≤x≤0.4, 0≤y≤0.07, and 0<z≤0.2;
forming an active layer overlying the multiplication layer, wherein,
the active layer comprises a pseudomorphic dilute nitride material; and
the dilute nitride material has a bandgap within a range from 0.7 eV and 1.2 eV; and
forming a second barrier layer overlying the active layer.
